(19) United States
(12) Patent Application Publication
(10) Pub. No.: US 2005/0009312 A1
(43) Pub. Date: Jan. 13, 2005

(54) GATE LENGTH PROXIMITY CORRECTED DEVICE

(75) Inventors: Shahid Butt, Ossining, NY (US); Wayne F. Ellis, Jericho, VT (US); John A. Gabric, Essex Junction, VT (US)

Correspondence Address: SCHMEISER, OLSEN + WATTS, SUITE 201, 3 LEAR JET, LATHAM, NY, 12033, US

(73) Assignees: INTERNATIONAL BUSINESS MACHINES CORPORATION, Armonk, NY (US); INFINEON NORTH AMERICA CORP, San Jose, CA (US)

(21) Appl. No.: 10/604,112

(22) Filed: Jun. 26, 2003

(51) Int. Cl. H01L 29/76

(52) U.S. Cl. 438/587; 257/412

(57) ABSTRACT

An electronic device including: a semiconductor substrate having an array of gate conductors, each having a length and a width, comprised of dummy gate conductors and functional gate conductors extending in a widthwise direction, the gate conductors positioned substantially parallel to each other in the widthwise direction and periodically spaced apart a fixed distance in a direction substantially perpendicular to the widthwise direction.

### BACKGROUND OF INVENTION

The present invention relates to the field of semiconductor devices; more specifically, it relates to a gate structure corrected for gate length proximity effects and the method of designing and fabricating the corrected gate structure.

As device sizes decrease gate lengths of devices decrease as well. Devices with very narrow gate widths are much more susceptible to photolithographic induced proximity effects. Proximity effects cause a printed gate to deviate from a nominal or designed gate length and width (or shape). Proximity effects are especially worrisome when many gates of different length and width occur in physical proximity because devices expected to have the same speeds could have different gate lengths and widths (hence different speeds), creating timing skews in circuits made from these devices.

### SUMMARY OF INVENTION

A first aspect of the present invention is an electronic device comprising: a semiconductor substrate having an array of gate conductors, each having a length and a width, comprised of dummy gate conductors and functional gate conductors extending in a widthwise direction, the gate conductors positioned substantially parallel to each other in the widthwise direction and periodically spaced apart a fixed distance in a direction substantially perpendicular to the widthwise direction.

A second aspect of the present invention is a method of fabricating an electronic device comprising: providing a semiconductor substrate; and forming on the substrate, an array of gate conductors, each having a length and a width, comprised of dummy gate conductor and functional gate conductors extending in a widthwise direction, the gate conductors positioned substantially parallel to each other in the widthwise direction and periodically spaced apart a fixed distance in a direction substantially perpendicular to the widthwise direction.

A third aspect of the present invention is a method of designing a device having a gate length and a gate width comprising: providing a design grid of gate shapes, each gate shape having a fixed width defined by opposite ends and extending in a widthwise direction, a useable fixed width less than the fixed width and a fixed length extending in a lengthwise direction, the lengthwise direction substantially perpendicular to the widthwise direction, the gate shapes arranged substantially parallel to each other in the widthwise direction and periodically spaced apart a fixed distance in the lengthwise direction; and forming a functional gate shape from one or more of the gate shapes.

### BRIEF DESCRIPTION OF DRAWINGS

The features of the invention are set forth in the appended claims. The invention itself, however, will be best understood by reference to the following detailed description of an illustrative embodiment when read in conjunction with the accompanying drawings, wherein:

FIG. 1A is top view of a device according to a first embodiment of the present invention;

FIG. 1B is a cross-sectional view through line 1B of FIG. 1A;

FIG. 1C is a cross-sectional view through line 1C of FIG. 1A;

FIG. 2 is a flowchart illustrating an exemplary fabrication method for practicing the present invention;

FIG. 3 is top view of a pair of devices according to a second embodiment of the present invention;

FIG. 4 is top view of a pair of devices according to a third embodiment of the present invention;

FIG. 5 is top view of a group of devices according to a fourth embodiment of the present invention;

FIG. 6 is top view of multiple devices illustrating the relationship between devices having different length gates according to the present invention; and

FIG. 7 is a flowchart illustrating conversion of device length and width parameters into layout width and length parameters.

### DETAILED DESCRIPTION

For the purposes of the present invention, the term device means a field effect transistor (FET), an N-channel FET (NFET) or a P-channel FET (PFET). The present invention is applicable as well, to all metal-oxide-silicon (MOS) and MOSFET devices having gate structures. The term gate length (or channel length) “L” is defined as the distance between the source/drains in an FET and defines a lengthwise direction. The term gate width (or channel width) “W” is defined as the length of the source/drains along a direction perpendicular to the gate length and defines a widthwise direction. A gate is defined as a patterned gate conductor over a gate dielectric.

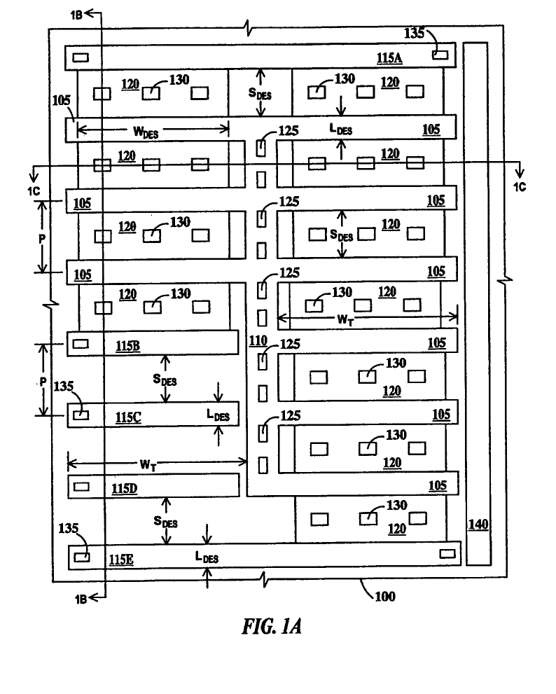

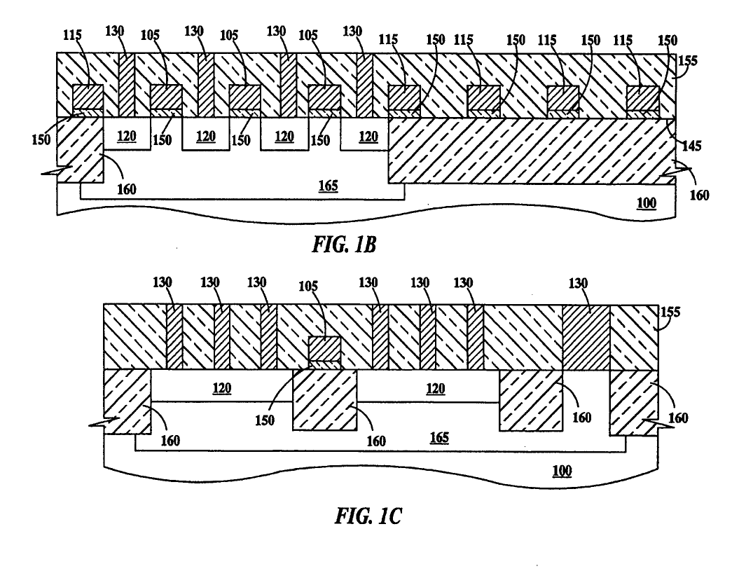

FIG. 1A is top view of a device according to a first embodiment of the present invention. In FIG. 1A, formed on a semiconductor substrate 100, such as a bulk silicon or silicon-on-insulator (SOI) substrate, are a multiplicity of parallel functional gate conductors 105 integral to and extending perpendicular from a spine 110 and a multiplicity of dummy gate conductors 115A through 115E. Dummy gate conductors 115A through 115E are arranged parallel to functional gate conductors 105. Each functional gate conductor 105 extends a distance W_{T} from spine 110. Functional gate conductors 105 and dummy gate conductor 115A through 115E are spaced apart from immediately adjacent to functional gate conductors or immediately adjacent to dummy gate conductors a distance S_{DES} and have a width L_{DES}. In one example, S_{DES} and L_{DES} are the minimum design groundrule distances. A pitch P=S_{DES}+L_{DES} may therefore be defined. The edges (or centers) of both functional gate conductors 105 and dummy gate conductor 115A through 115E are aligned on pitch P. Dummy gates 115A and 115E are not part of functional gates 105 and not connected to spine 110. Dummy gates 115B, 115C and 115D occupy positions relative to spine 110 that would have been occupied by functional gates in a larger device. Because of the alignment of dummy gate conductors 115B, 115C and 115D to P, it should also be noted that dummy gate conductors 115B, 115C and 115D are longitudinally aligned with functional gate conductors 105 on an opposite side of spine 110 from the dummy gate conductors.

Since dummy gate conductors 115A through 115E continue the pattern formed by functional gate conductors 105, proximity effects are or eliminated since adjacent gate conductors, whether functional or dummy, have the same or nearly the same length, the same width and are positioned on the same pitch “P.”

Formed in semiconductor substrate 100 is a multiplicity of source/drains (S/D) 120. Source drains 120 have a length W_{DES} and a width S_{DES}. W_{DES} defines the maximum extent of a S/D along a gate. W_{DES} is less than W_{T} in order to allow functional gate conductors 105 to extend past S/Ds 120 to avoid end effects in the FET formed by S/Ds 120 and functional gates 105. Since all functional gate conductors 105 are integrally formed with spine 110, a single FET is formed having a gate (or channel) length equal to L_{DES} and a gate (or channel) width equal to L_{DES} times the number of functional gate conductors 105. In the example of FIG. 1A, there are 9 functional gate conductors 105 so the width of the single FET is 9W_{DES}. Functional gate conductors 105 may be thought of as fingers extending from spine 110.

A multiplicity of gate contacts 125 are formed to spine 110 and a multiplicity of S/D contacts 130 are formed to S/Ds 120. A multiplicity of dummy gate contacts 135 are formed to dummy gate conductors 115A through 115E. A well contact 140 is formed to a well (not shown, see FIGS. 1B and 1C) in which S/Ds 120 are formed.

FIG. 1B is a cross-sectional view through line 1B of FIG. 1A and FIG. 1C is a cross-sectional view through line 1C of FIG. 1A. In FIGS. 1B and 1C, between each functional gate conductor 105 and dummy gate conductor 115 and a top surface 145 of substrate 100, a gate dielectric 150 is formed. S/D contacts 130 and well contact 140 are formed in an interlevel dielectric layer 155. A shallow trench isolation (STI) 160 is formed in substrate 100 and bounds S/Ds 120 which are formed in a well 165 of opposite doping type than the S/Ds.

Examples of dummy and functional gate conductors include polysilicon, doped polysilicon, aluminum, other metals and metal alloys. Examples of gate dielectrics include silicon oxide, silicon nitride, rare earth oxides, mixtures of rare earth oxides and combinations thereof.

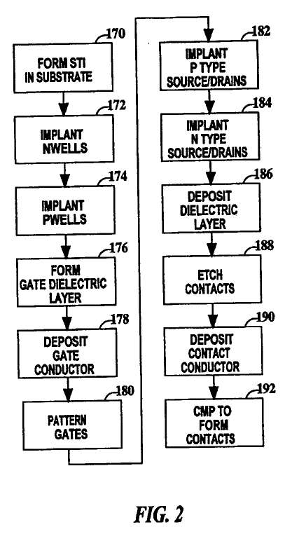

FIG. 2 is a flowchart illustrating an exemplary fabrication method for practicing the present invention. In step 170, STI is formed in a semiconductor substrate by, in one example, plasma etching trenches into the substrate through a micro-photolithographic defined hard mask, overfilling the trench with a dielectric material and chemical-mechanical-polish (CMP) of the excess dielectric material. The pattern used to define the STI also partially defines the S/D regions.

In step 172, N-wells are formed in the substrate in regions where PFETs are to be formed. In one example, N-wells are formed by ion-implantation of phosphorus or arsenic through a micro-photolithographic mask. In step 174, P-wells are formed in the substrate in regions where NFETs are to be formed. In one example, P-wells are formed by ion-implantation of boron through a micro-photolithographic mask.

In step 176, a gate dielectric layer is formed over the surface of the substrate and in step 178, a gate conductor is deposited over the gate dielectric. In one example, the gate dielectric and gate conductor are formed by chemical-vapor-deposition (CVD). In step 180, the gate conductor is formed into a pattern of functional gate conductors and dummy gate conductors. In one example, the gate conductor is patterned by plasma etching through a micro-photolithographic mask.

In step 182, P-type S/Ds are formed in the substrate in regions where PFETs are to be formed. In one example, P-type S/Ds are formed by ion-implantation of boron using the patterned gate conductor as a mask. In step 184, N-type S/Ds are formed in the substrate in regions where NFETs are to be formed. In one example, N-wells are formed by ion-implantation of phosphorus or arsenic using the patterned gate conductor as a mask.

In step 186, a dielectric layer is deposited over the substrate. In step 188, contact opening are formed (for example by plasma etching through a micro-photolithographic mask). In step 190, the contact openings are overfilled with a contact conductor (for example, with tungsten or another metal) and in step 192, a CMP is performed to remove of the excess contact conductor.

It should be understood that additional process steps, such as spacer formation on sidewalls of gate conductors and extension S/D implant steps may be performed.

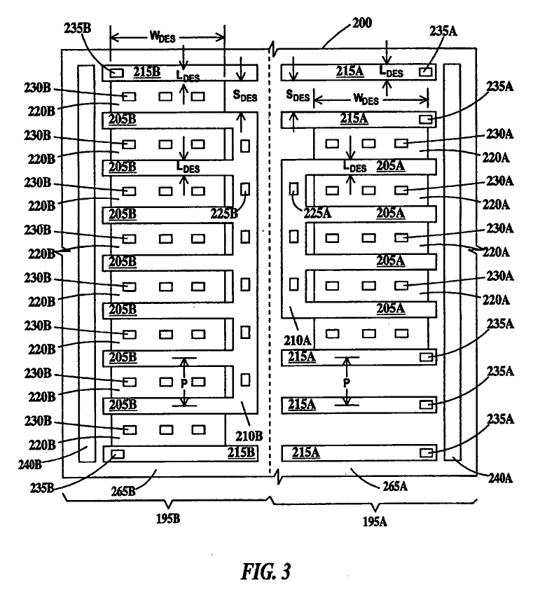

FIG. 3 is top view of a pair of devices according to a second embodiment of the present invention. FIG. 3 illustrates an NFET 195A and a PFET 195B formed adjacent to one another as would be used in forming the FETs of an inverter circuit.

In FIG. 3, formed on a semiconductor substrate 200, are a multiplicity of parallel functional gate conductors 205A and 205B integral to and extending perpendicular from spines 210A and 210B respectively and a multiplicity of dummy gate conductors 215A and 215B. Dummy gate conductors 215A and 215B are arranged parallel to respective functional gate conductors 205A and 205B. Functional gate conductors 205A and 205B and dummy gate conductor 215A and 215B are spaced apart from immediately adjacent functional gate conductors or immediately adjacent dummy gate conductors a distance S_{DES} and have a width W_{DES} and a channel length L_{DES}. Pitch P S_{DES}+L_{DES} is therefore the same as defined supra. Both functional gate conductors 205A and 205B and dummy gate conductor 215A and 215B are aligned on pitch P.

Since dummy gate conductors 215A and 215B continue the pattern formed by functional gate conductors 205A and 205B, proximity effects are reduced or eliminated since adjacent gate shapes, whether functional or dummy, have the same or nearly the same length, the same width and are placed on the same pitch.

Formed in semiconductor substrate 200 is a multiplicity of source/drains (S/D) 220A and 220B. S/Ds 220A are N-doped and S/Ds 220B are P-doped. Source drains 220A and 220B have a width W_{DES}. Since all functional gate conductors 205A are integrally formed with spine 220A, NFET 195A has a gate (or channel) length equal to L_{DES} and a gate (or channel) width equal to W_{DES} times the number of functional gate conductors 205A. In the example of FIG. 3, there are 4 functional gate conductors 205A so the gate width of NFET 195A is 4W_{DES}. Since all functional gate conductors 205B are integrally formed with spine 220B, PFET 195B is formed having a gate (or channel) length equal to L_{DES} and a gate (or channel) width equal to W_{DES} times the number of functional gate conductors 205B. In the example of FIG. 3, there are 7 functional gate conductors 205B so the width of PFET 195B is 7W_{DES}. NFET 195A has a smaller width than PFET 195B in order to equalize rise and fall times of the two device due to differences in mobility of the majority carriers in NFETs (electrons) and PFETS (holes).

A multiplicity of gate contacts 225A and 225B are formed respectively to spines 210A and 210B and a multiplicity of S/D contacts 230A and. 230B are formed respectively to S/Ds 220A and 220B. A multiplicity of dummy gate contacts 235A and 235B are formed respectively to dummy gate conductors 215A and 215B. Semiconductor substrate 200 includes an N-well region 265A and a P-well region 265B defined by the dashed line. An N-well contact 240A is formed to N-well 265A and a P-well contact 240B is formed to P-well 265B. Normally, N-well contact 240A is electrically connected to V_{DD} and P-well contact 240B is electrically connected to GND.

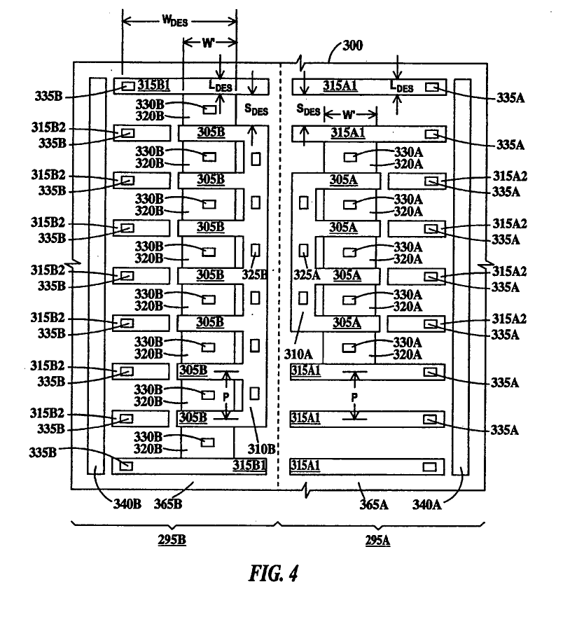

FIG. 4 is top view of a pair of devices according to a third embodiment of the present invention. FIG. 4 illustrates an NFET 295A and a PFET 295B formed adjacent to one another as would be used in forming the FETs of an inverter circuit. NFET 295A and PFET 295B are less wide than NFET 195A and PFET 195B of FIG. 3.

In FIG. 4, formed on a semiconductor substrate 300, is a multiplicity of parallel functional gate conductors 305A and 305B integral to and extends perpendicular from spines 310A and 310B respectively, and a multiplicity of dummy gate conductors 315A1, 315A2 and 315B1 and 315B2. Dummy gate conductors 315A1 and 315B1 are arranged parallel to respective functional gate conductors 305A and 305B. Dummy gate conductors 315A2 and 315B2 are arranged in line with respective functional gate conductors 305A and 305B. Functional gate conductors 305A and 305B and dummy gate conductor 315A1 and 315B1 are spaced apart from immediately adjacent functional gate conductors or immediately adjacent dummy gate conductors a distance S_{DES} and have a width W_{DES} and a channel length L_{DES}. Pitch P=S_{DES}+L_{DES} is therefore the same as defined supra. Both functional gate conductors 305A and 305B and dummy gate conductor 315A1, 315A2, 315B1 and 315B2 are aligned on pitch P.

Since dummy gate conductors 315A1, 315A2, 315B1 and 315B2 continue the pattern formed by functional gate conductors 305A and 305B, proximity effects are reduced or eliminated since adjacent gate shapes, whether functional or dummy, have the same or nearly the same length, the same width and are placed on the same pitch.

Formed in semiconductor substrate 300 is a multiplicity of source/drains (S/D) 320A and 320B. S/Ds 320A are N-doped and S/Ds 320B are P-doped. Source drains 320A and 320B have a length W′ which is less than W_{DES}. Since all functional gate conductors 305A are integrally formed with spine 330A, NFET 295A has a gate (or channel) length equal to L_{DES} and a gate (or channel) width equal to W_{DES} times the number of functional gate conductors 305A. In the example of FIG. 4 there are 4 functional gate conductors 305A so the width of NFET 195A is 4W′. Since all functional gate conductors 305B are integrally formed with spine 310B, PFET 295B has a gate (or channel) length equal to L_{DES} and a gate (or channel) width equal to W′ times the number of functional gate conductors 305B. In the example of FIG. 4 there are 7 functional gate conductors 305B so the width of PFET 295B is 7W′. Since the gate width of NFET 295A and PFET 295B are less than the gate width of respective NFET 195A and PFET 195B of FIG. 4, NFET 295A and PFET 295B have higher impedance and lower drive (current) capability than respective NFET 195A and PFET 195B of FIG. 4.

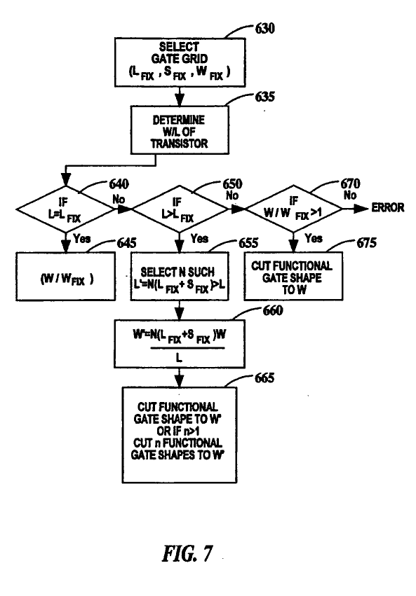

The relationship between gate or channel length of a device and L_{DES} and gate or channel width of a device and W_{DES} is described infra in reference to FIG. 7.

A multiplicity of gate contacts 335A and 335B are formed respectively to spines 310A and 310B and a multiplicity of S/D contacts 330A and 330B are formed respectively to S/Ds 330A and 330B. A multiplicity of dummy gate contacts 335A are formed to dummy gate conductors 315A1 and 315A2. A multiplicity of dummy gate contacts 335B are formed to dummy gate conductors 315B1 and 315B2. Semiconductor substrate 300 includes an N-well region 365A and a P-well region 365B defined by the dashed line. An N-well contact 340A is formed to N-well 365A and a P-well contact 340B is formed to P-well 365B. Normally, N-well contact 340A is electrically connected to V_{DD} and P-well contact 340B is electrically connected to GND.

An example methodology for designing NFET 295A would include: (1) laying out an array of spaced apart dummy conductor gate shapes corresponding to dummy gate conductors 315A1, (2) determining how many functional gate conductors are needed for NFET 295A, (3) determining the gate width required for NFET 295A, (4) “cutting” a selected number of dummy gate conductor shapes into functional gate conductor shapes by introducing a gap into the dummy gate conductor shapes and leaving the unused portions of the dummy gate conductor shapes in place and (5) connecting the functional gate conductor shapes with a spine shape corresponding to spine 310A.

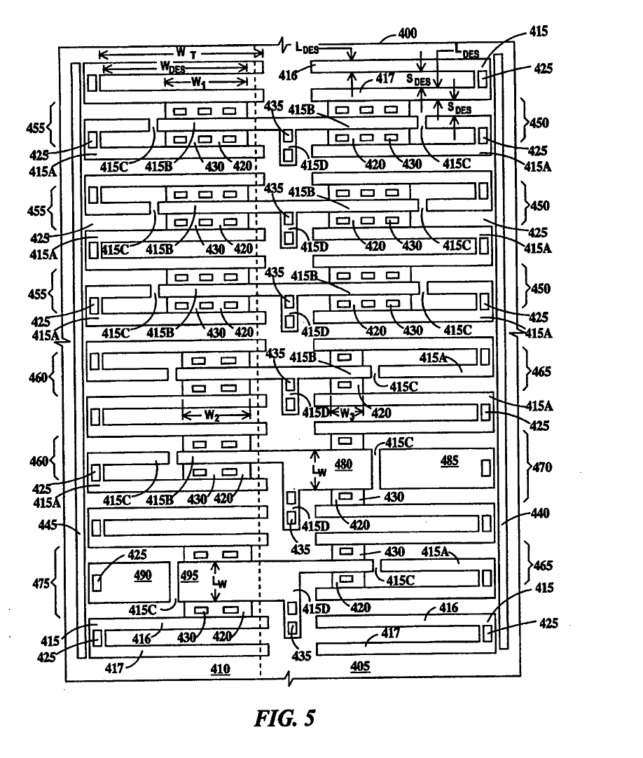

FIG. 5 is top view of a group of devices according to a fourth embodiment of the present invention. In FIG. 5, semiconductor substrate 400 includes an N-well region 405 and a P-well region 410 defined by the dashed line. An array of “U” shaped gate conductors 415 are formed on semiconductor 400. Fingers 416 and 417 of each gate conductor 415 are W_{T} wide, L_{DES} long and spaced a distance S_{DES} apart.

Some of the gate conductors 415 are divided into dummy gate conductors 415A and functional gate conductors 415B by introduction of gaps 415C. In FIG. 5, gate conductors 415 that are not divided into functional and dummy gate conductors are themselves dummy gate conductors. Integral “T” shaped gate conductor extension 415D joins pairs of functional gate conductors 415B positioned over oppositely doped wells. Functional gate conductors S/Ds 430 are positioned on either side of functional gate conductors 415B. S/D contacts 420, dummy gate conductor contacts 425, functional gate conductor contacts 435, an N-well contact 440 and a P-well contact 445 are added as appropriate.

Devices 450 are NFETS and devices 455 are PFETs having a gate length L_{DES} and a gate width of W₁. Devices 460 are PFETs having a gate length L_{DES} and a gate width of W₂. Devices 465 are NFETs having a gate length L_{DES} and a gate width W₃′ Device 470 is an NFET having a gate length L_{W} and a gate width W₃. Device 475 is a PFET having a gate length L_{W} and a gate width W₂. L_{W} is equal to 2L_{DES}+S_{DES}. The gate shape used to form the functional gate conductor 480 of device 470 and the corresponding dummy gate conductor 485 were modified by “filling” the interior of the “U” of the gate shape with an additional gate shape. The gate shape used to form the functional gate conductor 490 of device 475 and the corresponding dummy gate conductor 495 were modified by “filling” the interior of the “U” of the gate shape with an additional gate shape.

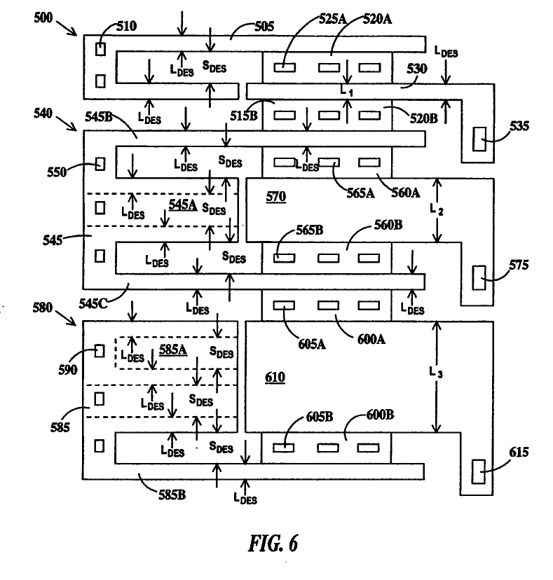

Since gate conductors 415, dummy gate conductors 415A and functional gate conductors 415B form a continuous pattern of parallel; and evenly spaced apart gate shapes, proximity effects are reduced or eliminated since adjacent gate shapes, whether functional or dummy are placed on the same pitch (L_{DES}+S_{DES}) or multiples thereof. The relationship between L (gate or channel length) of a device and L_{DES} and S_{DES} for permissible values of L is described infra in reference to FIG. 6.

FIG. 6 is top view of multiple devices illustrating the relationship between devices having different length gates according to the present invention. In FIG. 6, device 500 includes a dummy gate conductor 505 having dummy gate contacts 510, S/Ds 520A and 520B having respective S/D contacts 525A and 535B, and a functional gate conductor 530 (between S/Ds 520A and 520B) having a functional gate contact 535. Dummy gate conductor 505 has a physical width W_{DES} as does functional gate conductor 530. Dummy gate conductor 505 is positioned on an opposite side of S/D 520A from functional gate conductor 505 and a dummy gate conductor 545B is positioned on an opposite side of S/D 520B from functional gate conductor 505. Dummy gate conductors 505 and 545B are spaced a distance S_{DES} from functional gate conductor 530. The gate length of device 500 is L₁=L_{DES}.

Device 540 includes a dummy gate conductors 545A, 545B and 545C extending from and integral to a spine 545 and sharing dummy gate contacts 550, S/Ds 560A and 560B having respective S/D contacts 565A and 565B, and a functional gate conductor 570 (between S/Ds 560A and 560B) having a functional gate contact 575. Dummy gate conductors 545B and 545C have physical widths W_{DES}. Dummy gate conductor 545A, which is aligned longitudinally with functional gate conductor 570 and has a physical length 2L_{DES}+S_{DES} as does functional gate conductor 570. Dummy gate conductor 545B is positioned on an opposite side of S/D 560A from functional gate conductor 570 and dummy gate conductor 545C is positioned on an opposite side of S/D 560B from functional gate conductor 570. Dummy gate conductor 545A is spaced a distance S_{DES} from dummy gate conductor 545A and functional gate conductor 570. Dummy gate conductor 545C is spaced a distance S_{DES} from dummy gate conductor 545A and functional gate conductor 570. The gate length of device 540 is L₂=2L_{DES}+S_{DES}. The dashed lines illustrate how device 540 is designed from two “U” shapes similar to the “U” shape device 500 was designed from.

Device 580 includes dummy gate conductors 585A and 585B (dummy gate conductors 585A and 585B extending from a spine 585) having common dummy gate contacts 590, S/Ds 600A and 600B having respective S/D contacts 605A and 605B, and a functional gate conductor 610 (between S/Ds 600A and 600B) having a functional gate contact 615. Dummy gate conductor 585A has a physical length 3L_{DES}+2S_{DES} as does functional gate conductor 610. Dummy gate conductor 545C is positioned on an opposite side of S/D 600A from functional gate conductor 610 and dummy gate conductor 585B is positioned on an opposite side of S/D 600B from functional gate conductor 610. Dummy gate conductor 545C is spaced a distance S_{DES} from dummy gate conductor 590 and functional gate conductor 610. Dummy gate conductor 585B is spaced a distance S_{DES} from dummy gate conductor 585A and functional gate conductor 610. The gate length of device 580 is L₃=3L_{DES}+2S_{DE}. The dashed lines illustrate how device 580 is designed from two “U” shapes similar to the “U” shape device 500 was designed from.

A general formula for permissible gate widths according to the present invention is P_{ERMITTED}=nL_{FIX}+(n−1)S_{FIX} where P_{ERMITTED} is the device gate length, L_{FIX} is the smallest gate length permitted, S_{FIX} is a fixed repeating distance between gate conductors (functional or dummy) and n is a whole integer greater than zero. S_{FIX}+L_{FIX} define a periodic pitch that all gate conductors (dummy or functional) and hence all devices are designed and laid out to. In the examples illustrated in FIG. 6, L_{FIX}=L_{DES}, S_{FIX}=S_{DES} and P_{FIX}=L_{FIX}+S_{FIX}=L_{DES}+S_{DES}.

FIG. 7 is a flowchart illustrating conversion of device length and width parameters into layout width and length parameters. In step 630 a gate design grid is selected which is defined by L_{FIX}, S_{FIX} and W_{FIX}, where W_{FIX} is the longest device gate width permitted (W_{FIX} corresponds to W_{DES} described supra). In step 635, the gate width W and gate length L of the device to be designed is determined. Three possible conditions exist as determined in steps 640, 650 and 670.

If in step 640, L=L_{FIX} then in step 645 W is divided by W_{FIX} and the value obtained is the number of gate shapes to be tied together to form the device. For example, if W=100 and W_{FIX}=10 then 10 gate shapes need to be tied together. If the value of W/W_{FIX} is not a whole integer then the fractional gate shape is “cut” to W′. For example, if W=95 and W_{FIX}=10 then 9 and one-half gate shapes need to be tied together, so W′ is equal to 0.5. If in step 640 L s not equal to L_{FIX}, then in step 650, it is determined if L>L_{FIX}.

If in step 650, L>L_{FIX} then in step 655 a value for n and L′ is selected such that (1) L′=n(L_{FIX}+S_{FIX}) and (2) L′>L, where n is the smallest whole positive integer satisfying (1) and (2) and L′ is the new value for the gate width of the device being designed. Next in step 660, a value for W′ (the new gate width of the device being designed) is determined where W′=n(L_{FIX}+S_{FIX})(W/L). Then in step 665, if n=1 then the functional gate shape is “cut” to W′ from a single gate shape W_{FIX} long and the remainder of the gate shape (less a gap) is designated as a dummy gate shape. If n is greater than 1, then n functional gate shapes are “cut” to W′ from n gate shapes W_{FIX} long and the remainder of the gate shapes (less a gap) are designated as dummy gate shapes.

If in step 670, (W/W_{FIX})>1 then, in step 675, the functional gate shape is “cut” to W from a single gate shape W_{FIX} long and the remainder of the gate shape (less a gap) is designated as a dummy gate shape.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

1. An electronic device comprising:
a semiconductor substrate having an array of gate conductors, each having a length and a width, comprised of dummy gate conductors and functional gate conductors extending in a widthwise direction, said gate conductors positioned substantially parallel to each other in said widthwise direction and periodically spaced apart a fixed distance in a direction substantially perpendicular to said widthwise direction.

2. The electronic device of claim 1, wherein said functional gate conductors include conductors of at least two different widths.

3. The electronic device of claim 1, wherein said dummy gate conductors include conductors of at least two different widths.

4. The electronic device of claim 1, wherein said dummy gate conductors and functional gate conductors include conductors of the same width.

5. The electronic device of claim 1, further comprising additional dummy gate conductors positioned adjacent to ends of said functional gate conductors.

6. The electronic device of claim 5, wherein said additional dummy gate conductors are the same width as one of said functional gate conductors.

7. The electronic device of claim 1, wherein the length of said functional gate conductors is a function of positive integer multiples of a minimum length of said gate conductors and of positive integer multiples of said fixed distance.

8. The electronic device of claim 1, wherein the length of said dummy gate conductors is a function of positive integer multiples of a minimum length of said gate conductors and of positive integer multiples of said fixed distance.

9. The electronic device of claim 1, further including source/drains formed in said substrate underneath and proximate to said functional gate conductors.

10. The electronic device of claim 1, further including N-wells, P-wells or both N-wells and P-wells formed in said substrate underneath and proximate to said functional gate conductors.

11. The electronic device of claim 1, further including a gate dielectric formed between said gate conductors and said substrate.

12. A method of fabricating an electronic device comprising:
providing a semiconductor substrate; and
forming on said substrate, an array of gate conductors, each having a length and a width, comprised of dummy gate conductor and functional gate conductors extending in a widthwise direction, said gate conductors positioned substantially parallel to each other in said widthwise direction and periodically spaced apart a fixed distance in a direction substantially perpendicular to said widthwise direction.

13. The method of claim 12, wherein said functional gate conductors include conductors of at least two different widths.

14. The method of claim 12, wherein said dummy gate conductors include conductors of at least two different widths.

15. The method of claim 12, wherein said dummy gate conductors and functional gate conductors include conductors of the same width.

16. The method of claim 12, further comprising forming additional dummy gate conductor positioned adjacent to ends of said functional gate conductors.

17. The method of claim 16, wherein said additional dummy gate conductors are the same width as one of said functional gate conductors.

18. The method of claim 12, wherein the length of said functional gate conductors is a function of positive integer multiples of a minimum length of said gate conductors and of positive integer multiples of said fixed distance.

19. The method of claim 12, wherein the length of said dummy gate conductors is a function of positive integer multiples of a minimum length of said gate conductors and of positive integer multiples of said fixed distance.

20. The method of claim 12, further including forming source/drains in said substrate underneath and proximate to said functional gate conductors.

21. The method of claim 12, further including forming N-wells, P-wells or both N-wells and P-wells in said substrate underneath and proximate to said functional gate conductors.

22. The method of claim 12, further including a forming a gate dielectric between said gate conductors and said substrate.

23. A method of designing a device having a gate length and a gate width comprising:
providing a design grid of gate shapes, each gate shape having a fixed width defined by opposite ends and extending in a widthwise direction, a useable fixed width less than said fixed width and a fixed length extending in a lengthwise direction, said lengthwise direction substantially perpendicular to said widthwise direction, said gate shapes arranged substantially parallel to each other in said widthwise direction and periodically spaced apart a fixed distance in said lengthwise direction; and
forming a functional gate shape from one or more of said gate shapes.

24. The method of claim 23, wherein gate shapes and portions of gate shapes not used to form said functional gate shape are left in place as dummy gate shapes not connected to said functional gate shape.

25. The method of claim 23 further comprising, if said gate length is equal to said fixed length, connecting a whole number of gate shapes together along an end of each of said number of gate shapes, the number of gate shapes determined by dividing said gate width by said useable fixed width.

26. The method of claim 23 further comprising, if said gate length is greater than said fixed length, determining a minimum positive integer and a new gate length such that said new gate length is greater than said gate length and said new gate length is equal to said minimum positive integer times the sum of said fixed length and said fixed distance.

27. The method of claim 26, further including determining a new gate width by multiplying together the sum of said fixed length and said fixed distance, said minimum positive integer and said fixed gate width and dividing the result by said fixed gate length.

28. The method of claim 27, further including connecting a number gate shapes equal to said minimum positive integer of gate shapes together along an end of each of said number of gate shapes, each gate shape of said number of gates shapes having a width equal to said new gate width.

29. The method of claim 23 further including, if said gate width divided by said useable gate length is less than 1, forming said functional gate from a gate shape of a length equal to said gate width.
